(19) United States
(12) Patent Application Publication
(10) Pub. No.: US 2026/0057158 A1
(43) Pub. Date: Feb. 26, 2026

(54) INSTANTIATABLE AND STAMPABLE PARTITIONS FOR NETWORK-ON-CHIP ARCHITECTURE AND METHOD OF PROCESSING DATA USING THEREOF

(71) Applicant: SKYECHIP SDN BHD, BAYAN LEPAS, PULAU PINANG (MY)

(72) Inventors: Chee Hak TEH, BAYAN LEPAS (MY); Yu Ling ONG, BAYAN LEPAS (MY); Soon Chieh LIM, BAYAN LEPAS (MY)

(73) Assignee: SKYECHIP SDN BHD, BAYAN LEPAS, PULAU PINANG (MY)

(21) Appl. No.: 19/203,044

(22) Filed: May 8, 2025

(30) Foreign Application Priority Data
Aug. 22, 2024 (MY) PI2024004892

(51) Int. Cl. G06F 30/32

(52) U.S. Cl. CPC G06F 30/32

(57) ABSTRACT

The present invention relates to a network-on-chip architecture (100), characterized by: a plurality of stampable partition (200), each partition including one or more router (10) adapted for communication, registers and pre-built communication links established in cardinal directions or other directions, and one or more configuration bus node (20) deposited in each partition (200) connecting to the registers (40); a system integrator connecting a system operator (60) to one of the configuration bus node (20); wherein the system operator (60) initializes a path mapping between the configuration bus node (20) forming a secondary configuration network and access the registers (40) in each partition to program the registers (40) with routing data A method of processing data at the network-on-chip architecture (100) is also disclosed herein.

### TECHNICAL FIELD

The present invention relates generally to data processing using a network-on-chip architecture. More particularly, it relates to a network-on-chip architecture and a method for design, physical synthesis, and implementation of the network-on-chip architecture at a large scale.

### BACKGROUND ART

As the complexity of system-on-chip (SOC) designs continues to rise, traditional network-on-chip (NOC) architectures encounter limitations in scalability and design time. Existing network-on-chip designs require custom creation of each network partition, leading to repetitive effort and hindering efficient design of large network-on-chips for advanced system-on-chips. This growing need for efficient and scalable network-on-chip design methodologies motivate the development of a solution that streamlines the design process and enables post-fabrication configuration for optimized performance.

Below are several examples of prior arts related to network-on-chip architecture for data processing.

JP2009129447A discloses a network on chip (‘NOC’), the NOC comprising; integrated processor blocks, routers, memory communications controllers, and network interface controllers, each integrated processor block adapted to a router through a memory communication controller and a network interface controller, each memory communications controller controlling communication between integrated processor block and memory, each network interface controller controlling inter-integrated processor block communications through routers; the network organized into partitions, each partition including at least one integrated processor block, each partition assigned exclusive access to a unique physical memory address space; and one or more applications performing on one or more of the partitions.

US2009282211A1 discloses a data processing with a network on chip that includes integrated processor block, routers, memory communications controllers, and network interface controller, including; organizing the network partitions; assigning all integrated processor blocks of a partition a partition identifier that uniquely identifies for an integrated processor block a particular partition in which the integrated processor block is included; establishing one or more permissions tables associating partition integrated processors with sources and destinations of data communications of the network-on-chip, each record in the permissions tables representing a restriction on data communications on the network-on-chip; executing one or more applications on one or more of the partitions, including transmitting data communications messages among integrated processor blocks and between integrated processor blocks and memory, each data communications message including a partition identifier of a sender of the data communications message; and controlling data communications among the partitions in dependence upon the permissions tables and the partition identifiers.

It is evident that the existing network-on-chip architecture lack the focus on design efficiency and post-fabrication configuration offered by the present invention to adapt for large and complex network-on-chips.

### SUMMARY OF THE INVENTION

The following presents a simplified summary of the invention in order to provide a basic understanding of some aspects of the invention. This summary is not an extensive overview of the invention. Its sole purpose is to present some concepts of the invention in a simplified form as a prelude to the more detailed description that is presented later.

It is an objective of the present invention to enable the design of highly scalable network-on-chip for complex system-on-chip application.

It is also an objective of the present invention to significantly reduce the design effort and time required for physically implementing network-on-chip.

It is yet another objective of the present invention to enable post-fabrication configuration of routing paths and other operational parameters within the network-on-chip.

Accordingly, these objectives may be achieved by following the teachings of the present invention. The present invention relates a network-on-chip architecture, characterized by; a plurality of stampable partitions, each partitions including one or more routers adapted for communication, registers and pre-built communication links established in cardinal directions or directions, and one or more configuration bus node deposited in each partitions connecting to the registers; a system integrator connecting a system operator to one of the configuration bus nodes; wherein the system operator initializes a path mapping between the configuration bus nodes forming a secondary configuration network and access the register in each partitions to program the registers with routing data.

The present invention also relates to a method for physical synthesis and implementation of a network-on-chip architecture, comprising the steps of: partitioning a network-on-chip architecture into a plurality of partitions; characterized by selecting one or more of the partitions as stampable partitions; converting routing information of the selected partition to generic registers; establishing a superset pre-built communications links in the selected partition, wherein the links are established in cardinal directions or other directions; instantiating the selected partition multiple times to build a full network-on-chip architecture; and configuring the instantiated partitions using a secondary configuration network configured by a system integrator connecting a system operator and a plurality of configuration bus nodes in each partitions for physical synthesis and implementation of the network-on-chip architecture.

The foregoing and other objects, features, aspects, and advantages of the present invention will become better understood from a careful reading of a detailed description provided herein below with appropriate reference to the accompanying drawings.

### BRIEF DESCRIPTION OF THE DRAWINGS

So that the manner in which the above recited features of the present invention can be understood in detail, a more particular description of the invention, briefly summarized above, may have been referred by embodiments, some of which are illustrated in the appended drawings. It is to be noted, however, that the appended drawings illustrate only typical embodiments of this invention and are therefore not to be considered limiting of its scope, for the invention may admit to other equally effective embodiments.

These and other features, benefits, and advantages of the present invention will become apparent by reference to the following text figures, with like reference numbers referring to like structures across the views, wherein:

FIG. 1 is a diagram illustrating the interconnection of the network-on-chip components in accordance with an embodiment of the present invention;

FIG. 2 is a diagram illustrating the routing information embedded in node interface in accordance with an embodiment of the present invention;

FIG. 3 is a diagram illustrating the routing information embedded in router in accordance with an embodiment of the present invention;

FIG. 4 is a diagram illustrating the network-on-chip splitting into multiple unique partitions in accordance with an embodiment of the present invention;

FIG. 5 is a diagram illustrating the stampable partition with registers for configuration storage in accordance with an embodiment of the present invention;

FIG. 6 is a diagram illustrating the stampable partition with configuration bus node in accordance with an embodiment of the present invention;

FIG. 7 is a diagram illustrating the network-on-chip built with 2×3 partitions in accordance with an embodiment of the present invention; and

FIG. 8 is a diagram illustrating the network-on-chip without routing information but with configuration path mapped in accordance with an embodiment of the present invention.

### DETAILED DESCRIPTION OF THE INVENTION

As required, detailed embodiments of the present invention are disclosed herein; however, it is to be understood that the disclosed embodiments are merely exemplary of the invention, which may be embodied in various forms. Therefore, specific structural and functional details disclosed herein are not to be interpreted as limiting but merely as a basis for claims. It should be understood that the drawings and detailed description thereto are not intended to limit the invention to the particular form disclosed, but on the contrary, the invention is to cover all modifications, equivalents and alternatives falling within the scope of the present invention as defined by the appended claims. As used throughout this application, the word “may” is used in a permissive sense (i.e., meaning having the potential to), rather than the mandatory sense (i.e., meaning must). Similarly, the words “include,” “including,” and “includes” mean including, but not limited to. Further, the words “a” or “an” mean “at least one” and the word “plurality” means one or more, unless otherwise mentioned. Where the abbreviations or technical terms are used, these indicate the commonly accepted meanings as known in the technical field.

The present invention is described hereinafter by various embodiments with reference to the accompanying drawings, wherein reference numerals used in the accompanying drawings correspond to the like elements throughout the description. This invention may, however, be embodied in many different forms and should not be construed as limited to the embodiment set forth herein. Rather, the embodiment is provided so that this disclosure will be thorough and complete and will fully convey the scope of the invention to those skilled in the art. In the following detailed description, numeric values and ranges are provided for various aspects of the implementations described. These values and ranges are to be treated as examples only and are not intended to limit the scope of the claims. In addition, a number of materials are identified as suitable for various facets of the implementations. These materials are to be treated as exemplary and are not intended to limit the scope of the invention.

The present invention proposes a network-on-chip architecture (100) designed for scalability and post-fabrication configurability.

The network-on-chip architecture (100), characterized by: a plurality of stampable partitions, each partition (200) including one or more router (10) adapted for communication, registers and pre-built communication links established in cardinal directions or other directions, and one or more configuration bus node (20) deposited in each partitions (200) connecting to the registers (40); a system integrator connecting a system operator (60) to one of the configuration bus node (20); wherein the system operator (60) initialized a path mapping between the configuration bus nodes (20) forming a secondary configuration network and access the registers (40) in each partitions (200) to program the registers (40) with routing data.

In accordance with an embodiment of the present invention, the registers (40) of the network-on-chip architecture (100) are configured to store configuration details for routing and operation parameters.

In accordance with an embodiment of the present invention, the secondary configuration network is self-discovering and self-enumerating.

In accordance with an embodiment of the present invention, each partition (200) further comprises one or more register (40) and a processing element (50) configure with a node interface (30) each.

In accordance with an embodiment of the present invention, each of the partitions (200) comprises node interface identification, router identification, routing information and router link settings.

In accordance with an embodiment of the present invention, the system operator (60) is a power management unit or a system controller of a system-on-chip.

In accordance with an embodiment of the present invention, the pre-built communication links within stampable partition (200) are selected from a superset of cardinal direction or other directions. This flexibility in link configuration allows for customization based on the specific location and communication needs of the partition (200) within the network-on-chip architecture (100).

In accordance with an embodiment of the present invention, the combined pre-built communication links from stampable directions (200) provide connectivity in all necessary direction including north, east, west, and south. While individual partitions (200) may have a superset of pre-built links, the overall architecture (100) considers the combined functionality of all partitions (200). This ensures that when combining different stampable partitions (200) to create network-on-chip, there are enough communication links in all necessary directions including north, east, south, west, or even others for the architecture (200) to function properly.

The present invention also proposes a method for processing data using the network-on-chip architecture (100) described above.

The method comprises the steps of partitioning a network-on-chip architecture (100) into a plurality of partitions (200); characterized by selecting one or more of the partitions (200) as stampable partitions; converting routing information of the selected partition (200) to generic registers; establishing a superset pre-built communications links in the selected partitions (200), wherein the links are established in cardinal directions or other directions; instantiating the selected partition (200) multiple times to build a full network-on-chip architecture (100); and configuring the instantiated partitions (200) using a secondary configuration network configured by a system integrator connecting a system operator (60) and a plurality of configuration bus nodes (20) in each partition (200).

In accordance with an embodiment of the present invention, the step of configuring the instantiated partitions (200) using a secondary configuration network further comprising: connecting a system operator (60) to one of the configuration bus nodes (20); initializing path mapping by the configuration bus node (20); accessing the registers (40) in each partition (200); and programming the registers (40) with routing data.

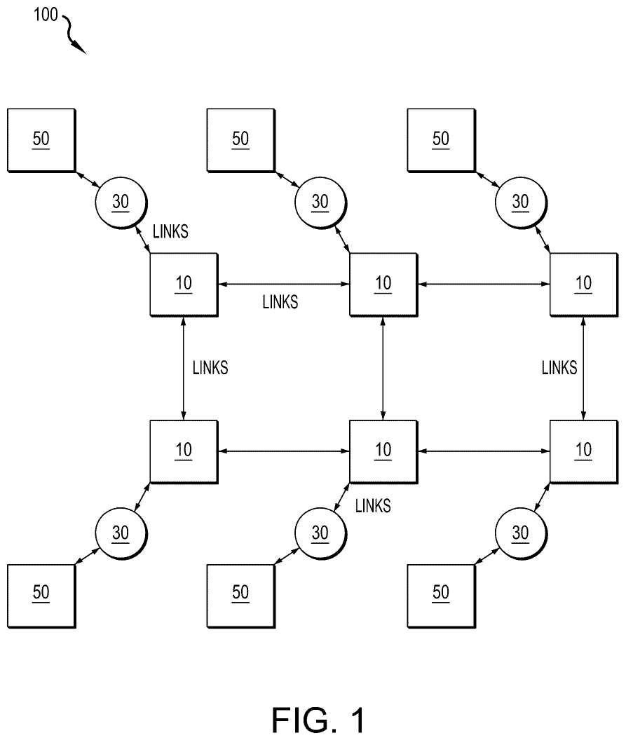

With reference to FIGS. 1 to 8, the invention will now be described in more details.

FIG. 1 illustrates an interconnection of network-on-chip components arranged in a 2×3 mesh topology. These components work together to facilitate communication between processing elements (50) on the chip. The processing elements (50), which can be Central Processing Units (CP Us), Graphics Processing Unites (GP Us), Digital Signal Processors (DSPs), accelerators, or any other type of processing unit and handle the actual computation task. Routers, acting as the network's nodes, connect the processing elements (50) and manage data flow. Each router (10) typically has multiple input and output ports for connections to neighboring routers (10) or processing elements (50). The node interface (30) bridges the gap between each processing element (50) and network-on-chip. It translates the processing element's (50) specific data transaction format, which is not limited to Advanced Extensible Interface (AXI), Coherent Interface (CHI), and Open Core Protocol (OCP), into the packet-based communication used by the network-on-chip, ensuring smooth data exchange. Connecting the routers (10) and processing elements (50) via links, which can be physical wires, on-chip interconnects, or other communication mediums. These links form the physical pathways for data transmission within the network.

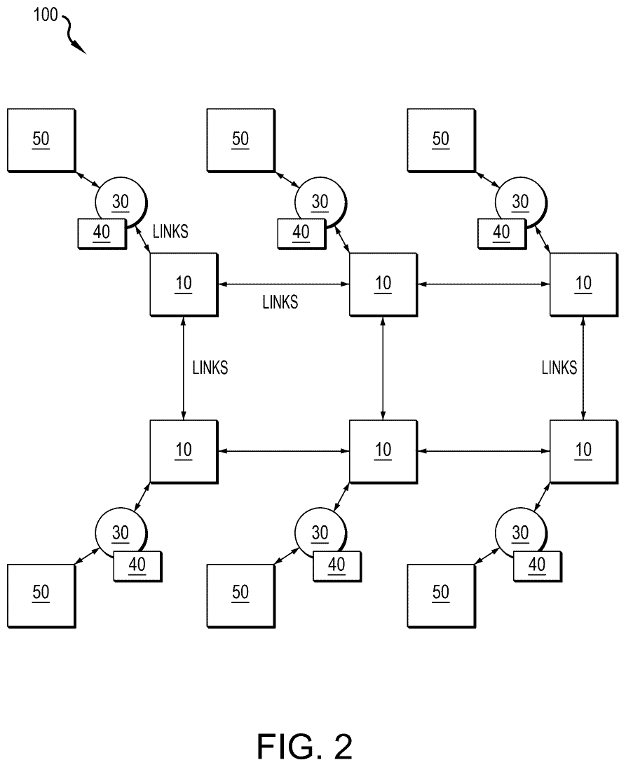

FIG. 2 illustrates the concept of routing information embedded in registers (40) within a node interface (30), a crucial element for transferring packets between processing elements (50). When sending data from a source processing element (50) to a destination, some form of routing scheme is needed to determine the path the packet will take. Several routing schemes exist, with two common examples being source routing and table-based routing. In source routing, the source node takes an active role, calculating the entire path for the packet and including this information directly in the packet header. As the packet traverses the network, each router (10) encountered acts like a signpost, extracting the next hop information from the header and forwarding the packet accordingly. In contrast, table-based routing relies on pre-computed routing tables stored within each router (10). These tables act as a map, translating destination addresses to the output ports of the next-hop routers. When a packet arrives at a router (10), it consults the router's table to determine the appropriate output port for forwarding, ensuring efficient delivery. Regardless of the chosen routing scheme, routing information needs a storage location. In source routing, this information resides within the source node interface (30), while in table-based routing, it is stored in each router (10).

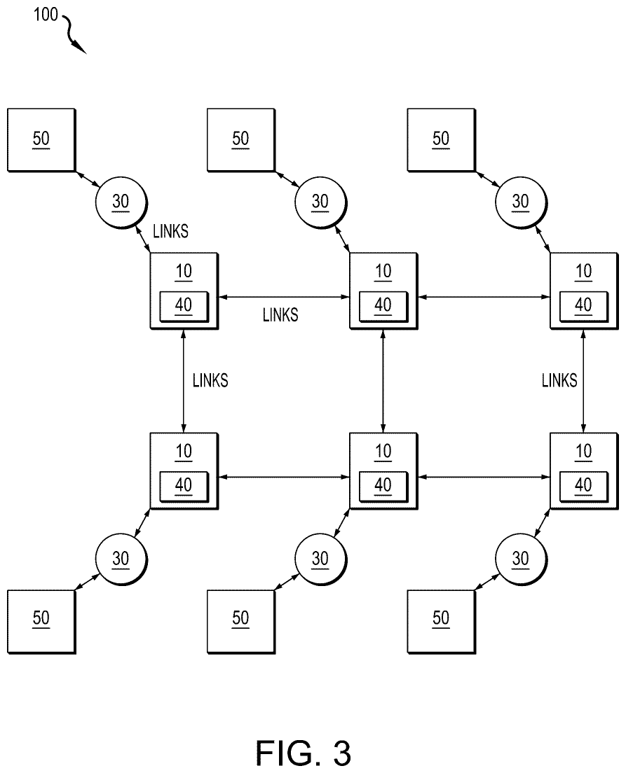

FIG. 3 illustrates the concept of routing information embedded within the router (10). This routing information is unique to each router (10) or node interface (30) that is contained in the registers (40).

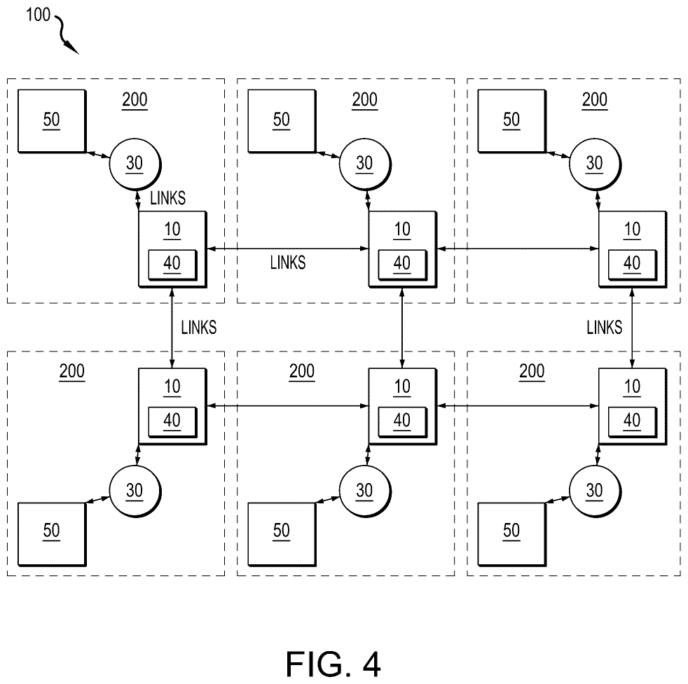

FIG. 4 illustrates a network-on-chip architecture (100) divided into multiple unique partitions (200). While each partition (200) is smaller in size, it remains unique due to its embedded routing information. Consequently, each partition (200) necessitates its own complete design cycle, encompassing logic synthesis, placement and routing, Design for Testability (DFT) insertion, and timing closure. If there are six such partitions (200), the design cycle must be repeated six times, resulting in minimal design time savings compared to a single-partition network-on-chip. The present invention involves partitioning the design into smaller blocks, similar to the existing approach. However, instead of creating entirely unique partitions, one partition is designated as the stampable partition (200). This partition (200) undergoes a transformation where its embedded routing information is converted into a generic register format. The registers (40) within the stampable partition (200) can store not only routing information but also any other data specific to each partition (200). Examples include identifiers, quality-of-service policies, arbitration weights, and configurations for enabling/disabling individual links. Another key characteristic of the stampable partition (200) is the presence of pre-built communication links, typically including north, east, south, and west, to facilitate both incoming (ingress) and outgoing (egress) traffic. However, the specific links included can be tailored to the original design to optimize area and routing resources. For example, if the original topology primarily involves horizontal traffic flow, only east and west links may be necessary.

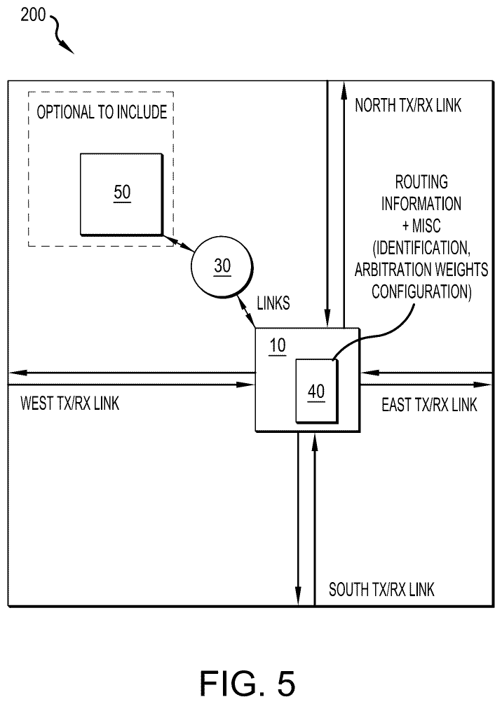

FIG. 5 illustrates a stampable partition (200) within a network-on-chip architecture (100). This partition (200) is characterized by the presence of registers (40) for configuration storage. While the depicted placement shows the registers (40) within the routers (10) themselves, it can also be situated in the node interface (30) or even within the processing elements (50), depending on the specific design requirements.

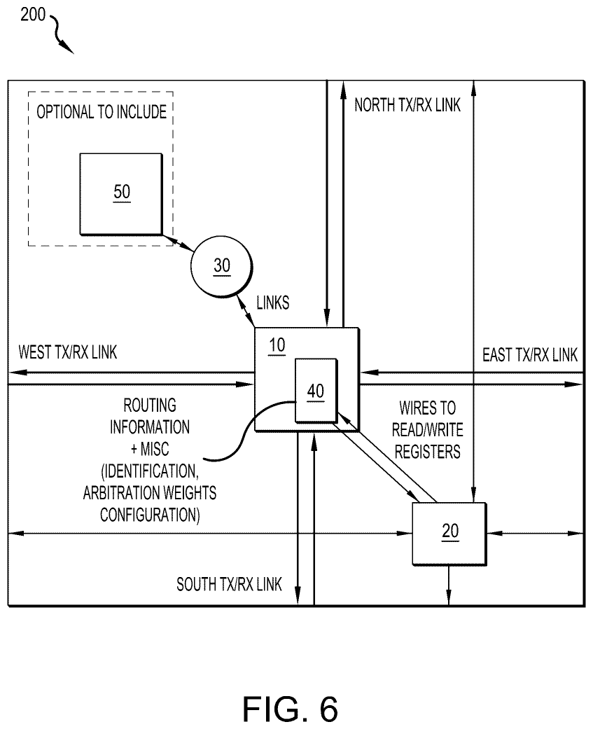

Hereinafter, examples of the present invention will be provided for more detailed explanation by referring to FIGS. 6 to 8. The advantages of the present invention may be more readily understood and put into practical effect by these examples. However, it is to be understood that the following examples are not intended to limit the scope of the present invention in any ways.

### EXAMPLES

### Example 1

FIG. 6 illustrates a stampable partition (200) within a network-on-chip architecture (200). Each partition (200) incorporates a configuration bus node (20) specifically designed to access registers (40). The configuration bus node (20) has read/write access to the registers (40) in the router (20), enabling the storage and retrieval of configuration data. While the diagram depicts the registers (40) residing within the router (10) itself, the configuration bus node's (20) functionality extends beyond this specific placement. The design offers flexibility in register (10) location. The registers (10) can be strategically placed within the stampable partition (200) to optimize design efficiency. While commonly situated in the router (40), alternative placement like the node interface (30) or even within the processing elements (50) are also feasible depending on the specific design requirements.

### Example 2

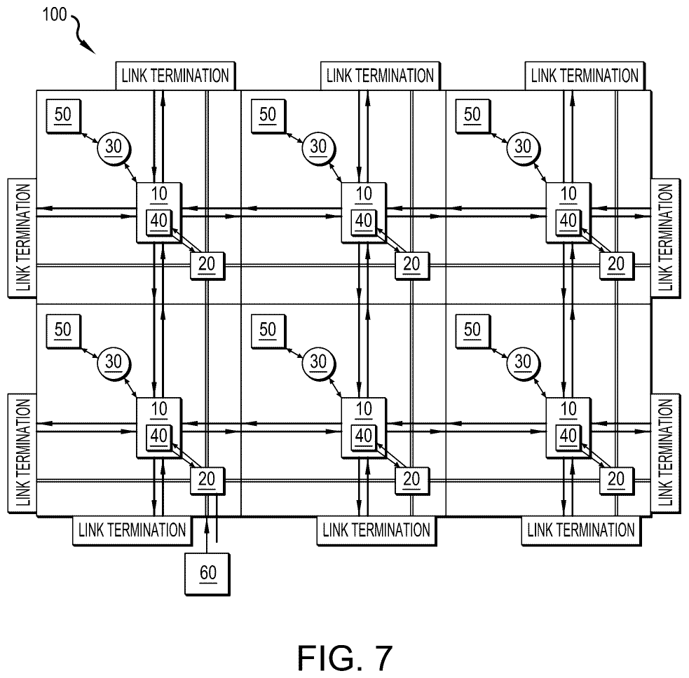

Moreover, the stampable partition (200) offers a significant advantage in design efficiency. Once this base unit has been created and successfully completed the design cycle—including synthesis, placement & routing, Design for Testability (DFT) insertion, and timing closure—the same design can be replicated numerous times to construct a complete network-on-chip. Leveraging the 2×3 mesh example from FIG. 1 to FIG. 4, FIG. 7 illustrates the process of stamping or instantiating the basic stampable partition (200) six times. This replication allows for the rapid creation of a complex network-on-chip architecture (100) without the need to individually design each partition (200), thereby significantly reducing design time and effort. Typically, a simple tie-off to ground is sufficient for termination to ensure proper signal integrity and prevent unexpected behavior within the network-on-chip. All unused links must be terminated according to standard physical and electrical design rules.

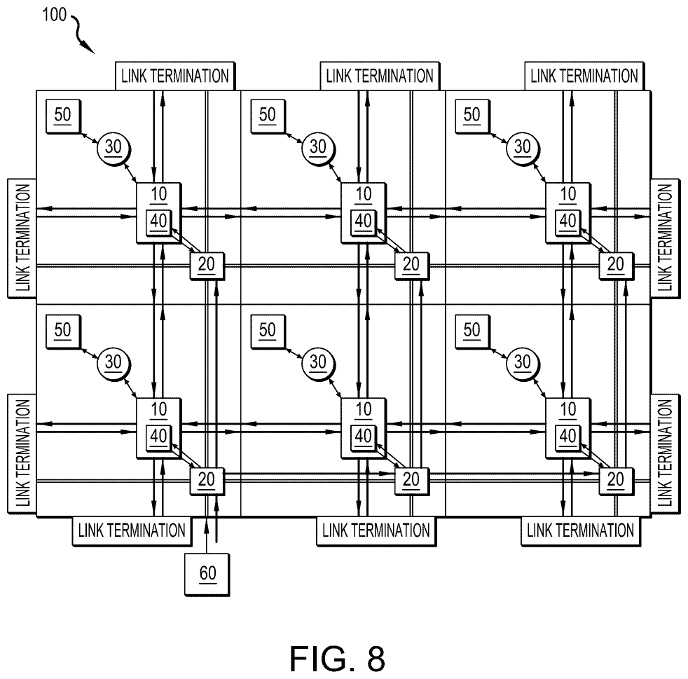

Furthermore, the configuration bus (20) offers a dedicated communication channel specifically designed for system integrators. This bus facilitates connection of the system operator (60) or the system controller of the system-on-chip to any of the configuration bus nodes (20). In the example above or as shown in FIG. 7, the chosen connection point is the southernmost configuration bus nodes (20) of the lower left-corner partition (200), enabling communication between the system operator (60) and the network-on-chip. During the initialization phase, the configuration bus node (20) utilizes a self-discovery and enumeration process. This process maps out the configuration paths within the network-on-chip, as illustrated in FIG. 8. Once this mapping is established, the system operator (60) can leverage the configuration bus node (20) to access the registers (40) within each router (10). Through this access, the system operator (60) can then program the registers (40) with the necessary routing information.

### Example 3

FIG. 8 showcases a 2×3 network-on-chip architecture (100) built using stampable partitions (200). Each partition (200), assigned a unique identifier from 1 to 6 for easy reference, contains configurable elements whose settings can vary depending on their location within the network-on-chip. These elements, typically implemented as registers (10), offer flexibility in configuration through the configuration bus node (20) or by pre-defining them with constant values during top-level system-on-chip integration. Crucially, these configurable elements allow for customization of the network-on-chip's behavior. A unique identifier, the node interface ID, specifies the specific node interface connected to the router (10) within the partition (200), essentially acting as its address. Another unique identifier, the router ID, distinguishes individual routers (10) within the network-on-chip. Routing information, determined by routing algorithms, defines the path packets taken within the network-on-chip, enabling communication between the processing elements (50). Finally, router link settings-encompassing link enable/disable functionality and arbitration mechanisms-control the behavior of communication links associated with the routers (10). These settings provide granular control over the network and can enable or disable specific links (North, South, East, West) to optimize communication flow within the network-on-chip. Additionally, these settings can potentially configure arbitration mechanisms, ensuring efficient link usage when multiple partitions (200) need to communicate simultaneously, thereby preventing congestion.

The following is an example setting for each individual partition (200):

### 1. Partition 1

a. Node interface ID=0
b. Router ID=0
c. Routing information=determined by routing algorithms allowing current processing element (50) to access other processing elements (50).
d. Router (10) link setting.
   i. Enable East and South link.
   ii. Disable North and West link.

### 2. Partition 2

a. Node interface ID=1
b. Router ID=1
c. Routing information=determined by routing algorithms allowing current processing element (50) to access other processing elements (50).
d. Router (10) link setting.
   i. Enable East, West, and South link.
   ii. Disable North link.

### 3. Partition 3

a. Node interface ID=2
b. Router ID=2
c. Routing information=determined by routing algorithms allowing current processing element (50) to access other processing elements (50).
d. Router (10) link setting.
   i. Enable West and South link.
   ii. Disable North and East link.

### 4. Partition 4

a. Node interface ID=4
b. Router ID=4
c. Routing information=determined by routing algorithms allowing current processing element (50) to access other processing elements (50).
d. Router (10) link setting.
   i. Enable East and North link.
   ii. Disable South and West link.

### 5. Partition 5

a. Node interface ID=5
b. Router ID=5
c. Routing information=determined by routing algorithms allowing current processing element (50) to access other processing elements (50).
d. Router link (10) setting.
   i. Enable East, West, and North link.
   ii. Disable South link.

### 6. Partition 6

a. Node interface ID=6
b. Router ID=6
c. Routing information=determined by routing algorithms allowing current processing element (50) to access other processing elements (50).
d. Router (10) link setting.
   i. Enable West and North link.
   ii. Disable South link.

In summary, the stampable partition concept revolutionizes network-on-chip architecture (100). By enabling replication of a pre-designed and verified units, it dramatically reduces design time and effort. This approach empowers the creation of complex network-on-chip systems using a modular and a scalable methodology. Communication between the system controller (60) and the network-on-chip is facilitated by a configuration bus node (20). The example provided showcases the construction of desired network-on-chip architecture (100) using a single type of stampable partition (200). However, the invention extends beyond this example allowing for the creation of multiple stampable partition (200) types. This different type can be combined or mixed-and-matched to form even more intricate and area optimized network-on-chip architecture (100).

The present invention addresses the limitations of the existing network-on-chip architecture (100) using traditional bus-based architectures which struggle to keep pace with the ever-increasing demands for scalability and performance in modern system-on-chip applications. The stampable partition (200) concept tackles this head-on by introducing a highly scalable and efficient design process. By enabling the reuse of pre-designed and verified network-on-chip building blocks, this invention dramatically reduces design time and effort. Furthermore, a dedicated configuration bus node (20) simplifies communication between the system operator (60) and the network-on-chip, while configurable elements within each partition (200) allow for customization based on its location. This flexibility empowers the creation of complex, high-performance network-on-chip architecture (100) that can effectively manage the ever-growing communication demands within modern system-on-chips.

Various modifications to these embodiments are apparent to those skilled in the art from the description and the accompanying drawings. The principles associated with the various embodiments described herein may be applied to other embodiments. Therefore, the description is not intended to be limited to the embodiments shown along with the accompanying drawings but is to be providing broadest scope of consistent with the principles and the novel and inventive features disclosed or suggested herein. Accordingly, the invention is anticipated to hold on to all other such alternatives, modifications, and variations that fall within the scope of the present invention and appended claim.

In the claims which follow and in the preceding description of the invention, except where the context requires otherwise due to express language or necessary implication, the word “comprise” or variations such as “comprises” or “comprising” is used in an inclusive sense, i.e. to specify the presence of the stated features but not to preclude the presence or addition of further features in various embodiments of the invention.

### DESCRIPTION OF FIGURES

| | |
|---|---|
| 100 | Network-on-chip architecture |
| 200 | Partition |
| 10 | Router |
| 20 | Configuration bus node |
| 30 | Node interface |
| 40 | Register |
| 50 | Processing element |
| 60 | System operator |

1. A network-on-chip architecture, comprising:
a plurality of stampable partitions, each partition including one or more router adapted for communication, registers and pre-built communication links established in cardinal directions or other directions, and one or more configuration bus node deposited in each partition connecting to the registers; and
a system integrator connecting a system operator to one of the configuration bus nodes,
wherein the system operator initializes a path mapping between the configuration bus nodes forming a secondary configuration network and access the registers in each partition to program the registers with routing data.

2. The network-on-chip architecture as claimed in claim 1, wherein the registers configured to store configuration details for routing and operation parameters.

3. The network-on-chip architecture as claimed in claim 1, wherein the secondary configuration network is self-discovering and self-enumerating.

4. The network-on-chip architecture as claimed in claim 1, wherein each partition further comprises, one or more register and a processing element configure with a node interface each.

5. The network-on-chip architecture as claimed in claim 1, wherein each of the partitions comprises node interface identification, router identification, routing information and router link settings.

6. The network-on-chip architecture as claimed in claim 1, wherein the system operator is a power management unit or a system controller of a system-on-chip.

7. The network-on-chip architecture as claimed in claim 1, wherein the pre-built communication links within stampable partition are selected from a superset of cardinal directions or other directions.

8. The network-on-chip architecture as claimed in claim 1, wherein the combined pre-built communication links from stampable partitions provide connectivity in all necessary direction including north, east, west, and south.

9. A method of processing data using a network-on-chip architecture as claimed in claim 1, further comprising:
partitioning a network-on-chip architecture into a plurality of partitions; characterized by
selecting one or more of the partitions as stampable partitions;
converting routing information of the selected partition to generic registers;
establishing a superset pre-built communications links in the selected partitions, wherein the links are established in cardinal directions or other directions;
instantiating the selected partition multiple times to build a full network-on-chip architecture; and
configuring the instantiated partitions using a secondary configuration network configured by a system integrator connecting a system operator and a plurality of configuration bus nodes in each partition.

10. The method as claimed in claim 9, wherein configuring the instantiated partitions using a secondary configuration network further comprising:
connecting a system operator to one of the configuration bus nodes;
initializing path mapping by the configuration bus node;
accessing the registers in each partition; and
programming the registers with routing data.
